(19) United States
(12) Patent Application Publication
(10) Pub. No.: US 2004/0098991 A1
(43) Pub. Date: May 27, 2004

(54) Thermoelectric control of fluid temperature

(76) Inventor: Keith James Heyes, Worcestershire (GB)

Correspondence Address: Sten Erik Hakanson, Patent Attorney, IMI Cornelius Inc, One Cornelius Place, Anoka, MN, 55303-6234, US

(21) Appl. No.: 10/363,512

(22) PCT Filed: Aug. 31, 2001
(86) PCT No.: PCT/GB01/03880

(30) Foreign Application Priority Data
Aug. 31, 2000 (GB) 0021393.4

(51) Int. Cl. F25B 21/02; H01L 35/28

(52) U.S. Cl. 62/3.64; 62/3.7; 136/204

(57) ABSTRACT

A thermoelectric module (1) has a plurality of thermoelectric devices (2) integral with heat conducting surfaces (5, 5′) of fluid chambers (3, 3′). The thermoelectric devices (2) are operable to transfer heat to or from fluids in the chambers (3, 3′). A product, eg a beverage, flowing through one of the chambers (3, 3′) can be heated or cooled to achieve a desired product temperature by selective operation of the thermoelectric devices (2). The module (1) provides an integrated unit that avoids inefficient boundaries between the heat conducting surfaces (5, 5′) and the thermoelectric devices (2).

This invention relates to thermoelectric control of fluid temperature. More particularly, the invention concerns apparatus employing thermoelectric heating/cooling to control the temperature of a liquid. The invention has application especially, but not exclusively, to the dispense of beverages such as beers, lagers, and soft drinks (carbonated and uncarbonated) having a desired temperature. The invention also concerns a method of manufacturing the apparatus.

Thermoelectric devices known as Peltier plate assemblies are well known and provide a structure which, when connected to a voltage supply, produces a hot side and a cold side. Fluid may be cooled by passage into contact with the cold side and the hot side may be cooled by passage into contact with it of a coolant, i.e. to provide a heat exchanger arrangement.

It is already known to use thermoelectric devices for cooling beverages to a desired temperature for dispense by arranging the cold side to transfer heat from the beverage and the hot side to transfer heat to a coolant. Typically, many thermoelectric devices are required in order to achieve the required cooling of the beverage. In a common arrangement, a thermoelectric module is provided by clamping the thermoelectric devices between a flat heat conducting surface of a flow line for the beverage to be cooled and a flat heat conducting surface of a flow line for the coolant. The transfer of heat between the heat conducting surfaces and the thermoelectric devices is relatively inefficient and a grease is usually provided to improve the thermal contact. As a result, assembly of the thermoelectric module is complicated and time consuming and manufacturing costs are relatively high.

Thus, it is an object of the present invention to provide a thermoelectric module for heating or cooling a fluid that mitigates at least some of the problems and disadvantages of existing thermoelectric modules.

According to a first aspect, the present invention provides a thermoelectric module comprising a first flow line for a first fluid, a second flow line for a second fluid, and at least one thermoelectric device between a heat conducting surface of the first flow line and a heat conducting surface of the second flow line characterised in that the thermoelectric device is integral with the heat conducting surfaces of the first and second flow lines.

By this invention, the efficiency of the heat transfer between the hot and cold sides of the thermoelectric device and fluids in the flow lines is improved by forming the flow lines and the thermoelectric device as an integrated unit. In this way, inefficient boundaries for heat transfer between the thermoelectric devices and the flow lines are eliminated and use of grease to enhance thermal contact is avoided. As a result, manufacture and assembly of the invented thermoelectric module may be facilitated with possible cost savings.

Preferably, the thermoelectric device comprises a plurality of thermoelectric elements comprising a printed electrically conducting circuit layer on each side of a central semi-conductor layer which may be a conventionally used layer of known semi-conductor composition as currently used in conventional thermoelectric modules.

The heat conducting surfaces of the first and second flow lines may be, for example, of metal or ceramic, and are preferably chosen, in addition to their heat conducting properties, to be compatible with the first and second fluids passed across them in the first and second flow lines, for example beverages and coolants. Stainless steel or aluminium may be particularly preferred for use with beverages but it will be understood other materials may be employed.

Where the heat conducting surface of either flow line is of an electrically conducting material, e.g. a metal, a layer of electrically insulating material, e.g. a glaze, should be applied between the heat conducting surface and the adjacent electrically conducting circuit layer. For example, the glaze layer may be applied to the heat conducting surface and the electrically conducting circuit layer printed onto the surface of the glaze layer. The printed circuit layer may be formed by silk screen printing of a suitable emulsion, which is dried by conventional means and may consist of several printed layers that are heated to melt and flow to form a single layer. Where the heat conducting surface of either flow line is not electrically conducting, e.g. ceramic, the glaze layer may be omitted and the electrically conducting circuit layer printed onto the surface of the heat conducting surface.

Where provided, the glaze may be of any suitable glaze material and may need to contain thermally conductive material, e.g. powder, to provide the necessary degree of thermal conductivity. An example of a suitable powder is aluminium nitride. This glaze layer, therefore, provides an electrically non-conductive base on which to print the electrically conducting circuit layer but maintains acceptable thermal conduction.

The printed electrically conducting circuit layer is preferably of silver and a protective barrier layer provided to prevent poisoning of the semi-conductor layer by the silver. The barrier layer may be, e.g. of gold, applied over the printed circuit layer. Alternatively, the barrier layer may be, e.g. of nickel, applied to the semi-conductor layer.

The printed electrically conducting circuit layer, covered where necessary by the protective barrier layer, is preferably soldered to the semiconductor layer. Moreover, the printed electrically conducting circuit layer may be masked, for example with a lacquer, in all regions where components are not to be attached to it. This can prevent migration of, for example, the silver.

The heat conducting surface of each flow line may conveniently be provided by a plate of rectangular shape for securing to a matching plate to form a fluid chamber of rectangular section having an inlet at one end and an outlet at the other end for connection of the flow line to a fluid line. Inserts may be added to direct the flow or to provide turbulence to the flow between the inlet and outlet.

The plates may be hardened to increase stiffness and thereby provide increased support for the module. The plates may be formed to give mechanical strength in key areas. A bursting disc to relieve excess pressure may be etched into the plates. The plates may be joined together by various methods to form the chamber, e.g. plasma welding, vacuum brazing, mechanical crimping and laser welding.

The thermoelectric device is preferably applied to a flat area or region of each heat conducting surface and the thermoelectric module may comprise a plurality of thermoelectric devices between and integral with the heat conducting surfaces of the first and second flow lines to provide a desired cooling/heating capability. For example, thermoelectric modules providing cooling of 200-300 watts may be suitable for cooling beverages.

Preferably, stress relief means is provided to counter the effect of thermal expansion and contraction of the module caused by heating and cooling of the fluids. Thus, the heating and cooling of fluids by heat transfer across the heat conducting surfaces of the flow lines may generate forces affecting the integrity of the module due to thermal expansion and contraction of the module. For example, shear stresses may be produced between the layers of the thermoelectric device(s) sufficient to cause separation of the layers.

This may not be a significant problem in modules having a small number of thermoelectric devices providing a low cooling capability where the thermal gradient across the module is low. However, substantial forces may be generated in modules having many thermoelectric devices providing much higher cooling capability, e.g. of the order of 200-300 watts envisaged for modules to be used for cooling beverages.

According to a second aspect, the present invention provides a thermoelectric module for heating a first fluid and cooling a second fluid comprising at least one thermoelectric device integral with a pair of spaced heat conducting surfaces for contact with the first and second fluids respectively, and means for relieving stress caused by thermal expansion and contraction of the module.

The stress relief means may provide flexing in selected areas or regions to reduce stresses within the module and assist in maintaining integrity of the module. For example, the heat conducting surfaces of each flow line may be formed with one or more lands separated by channels. The lands provide flat areas or regions for applying one or more thermoelectric devices and the channels help to relieve stress during thermal expansion and contraction of the module and counter stresses to assist in maintaining the integrity of the module. In particular, the stress relief means helps to prevent separation of the layers of the thermoelectric device(s) caused by shear stresses due to thermal expansion and contraction of the module.

The heat conducting surfaces may be pre-formed with the stress relief means prior to formation of the thermoelectric device(s) and assembly of the module. For example, where the heat conducting surfaces are provided by metal plates, the plates may be pressed or otherwise shaped to form the stress relief means.

Other means of stress relief may be employed. For example, where the thermoelectric devices are joined to the heat conducting surfaces, the joint is preferably dimensioned and shaped at its edges to have some “give” during any thermal movement. This gives some flexibility to the joint that can help to counter stresses due to thermal expansion and contraction of the thermoelectric module and reduce the risk of the thermoelectric device(s) separating from the heat conducting surfaces.

Stress relief may also be provided by locally reducing the thickness of the heat conducting surfaces in the region of the thermoelectric device(s) to reduce thermal gradients and/or by providing the heat conducting surfaces with slots or similar formations adjacent to the thermoelectric device(s) to act like springs. These may be formed by, for example, chemical etching where the heat conducting surfaces are made of metal.

The invented thermoelectric module provides a complete integrated assembly having heat conducting surfaces suitable for direct contact with fluids, e.g. water, carbonated water, hot and cold beverages, beer, wine and cider, together with the thermoelectric devices. As indicated above, the thermoelectric devices may employ conventionally used semiconductors and the semi-conductor layer will usually comprise a plurality of such “chips” or blocks in side by side relation.

The invention is particularly useful for liquid/liquid and liquid/gas, e.g. air, heat transfers with one of the fluids passing in contact with the cooling stainless steel surface and the other with the hot stainless steel surface. It may equally, however, be useful for gas/gas transfers.

The layers can readily be assembled, using printing techniques for most of the layers, and inefficient boundaries, e.g. using thermal grease, are eliminated. The thermoelectric elements may be assembled by the well known pick and place and vapour phase reflow assembly techniques. These elements may be used in a carrier to assist in stress relief during thermal expansion and contraction.

The operation and performance of the invented module may be further enhanced by one or more of the following features.

Thermistors may be printed onto the electrically conducting circuit layer to assist with temperature control of the module. Heating and cooling zones can be arranged to give selective control.

A control circuit may be mounted on the same substrate as the semi-conductor thermoelectric elements and the module may be designed to operate from mains electricity supply.

Pressure sensors may be printed onto the module. These can sense the presence or absence of coolant or product through absolute pressure and/or sense flow/no flow through differential pressure and can thereby control the different cooling rates needed for flowing and static product.

The heat conducting surfaces of the flow lines, e.g., stainless steel plates, may be modified, e.g. by chemical etching, to provide an increase in thermal transfer by increasing turbulence and/or to form fluid channels to give increased flow paths.

The number and arrangement of the thermoelectric devices may be chosen to provide the module with any desired cooling power. The cooling power may be adjustable by controlling the power supply to the thermoelectric devices according to the cooling requirement. Alternatively or additionally, two or more modules may be combined to give multiples of the basic unit cooling power.

According to a third aspect, the present invention provides a method of manufacturing a thermoelectric module comprising providing first and second spaced heat conducting surfaces and forming a thermoelectric device between the first and second heat conducting surfaces with an outer layer on each side of a semi-conductor layer integral with the first and second heat conducting surfaces whereby the first and second heat conducting surfaces form an integrated unit with the thermoelectric device.

A plurality of thermoelectric devices may be formed between the first and second heat conducting surfaces which may be arranged to form part of fluid chambers for passage of fluids to be heated or cooled by direct contact with the heat conducting surfaces.

According to a fourth aspect, the present invention provides a thermoelectric cooler for a beverage, the cooler comprising a heat conducting surface for a beverage to be cooled, a heat conducting surface for a coolant, the heat conducting surfaces being connected by at least one thermoelectric device integral with the heat conducting surfaces such that, in use, a cold side of the or each thermoelectric device is arranged to remove heat from a beverage, and a hot side of the or each thermoelectric device is arranged to transfer heat to a coolant.

The thermoelectric cooler may be provided in a beverage supply line for controlling the dispense temperature of a beverage delivered to a dispense point, for example a tap. The thermoelectric cooler may be used to control the dispense temperatures of alcoholic beverages such beers, lagers and non-alcoholic beverages (carbonated and uncarbonated) such as colas, fruit juices and water. More than one thermoelectric cooler may be provided to achieve the required cooling, for example two or more coolers may be connected in series with suitable control means for controlling operation in response to a particular cooling requirement.

According to a fifth aspect, the present invention provides a beverage dispense system comprising a source of a beverage to be dispensed, a supply line for delivering the beverage from the source to a dispense point, and at least one thermoelectric cooler according to the fourth aspect of the invention positioned between the source and the dispense point for lowering the temperature of the beverage to a required temperature for dispense.

According to a sixth aspect, the present invention provides a method of controlling a dispense temperature of a beverage comprising providing a supply of a beverage at a first temperature and cooling the beverage to a second temperature corresponding substantially to a desired dispense temperature by passage through a thermoelectric module having a cold surface for contact with the beverage and a hot surface for contact with a coolant, and at least one thermoelectric device integral with the hot and cold surfaces.

Other features, benefits and advantages of the invention in its various aspects will be apparent from the detailed description hereinafter of exemplary embodiments.

The invention will now be described, by way of example only, with reference to the accompanying drawings in which;

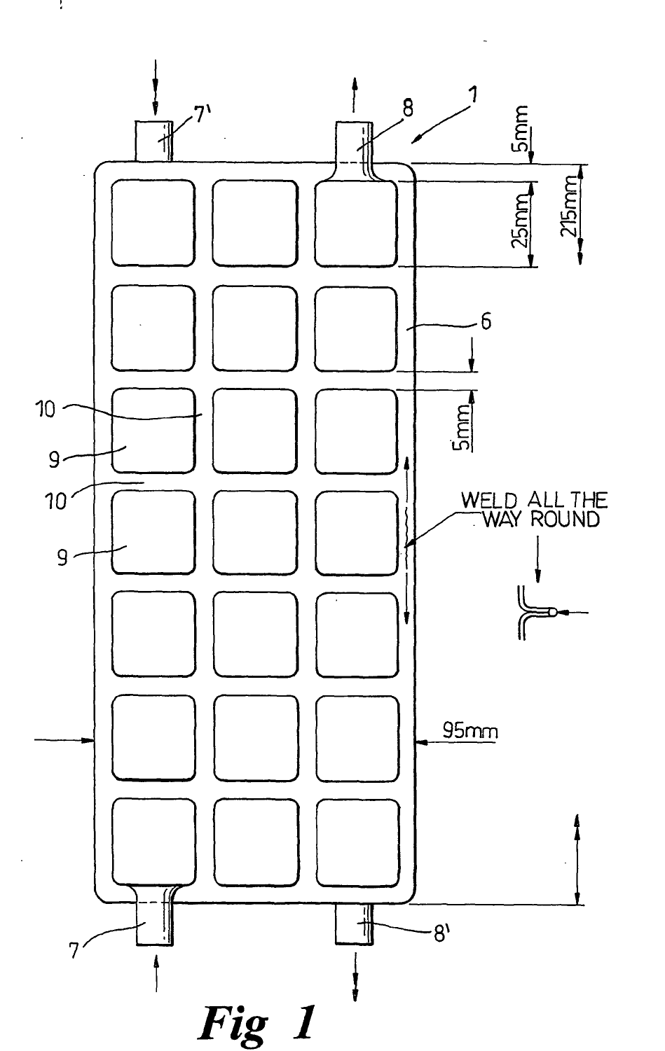

FIG. 1 is a plan view of a thermoelectric module according to the present invention;

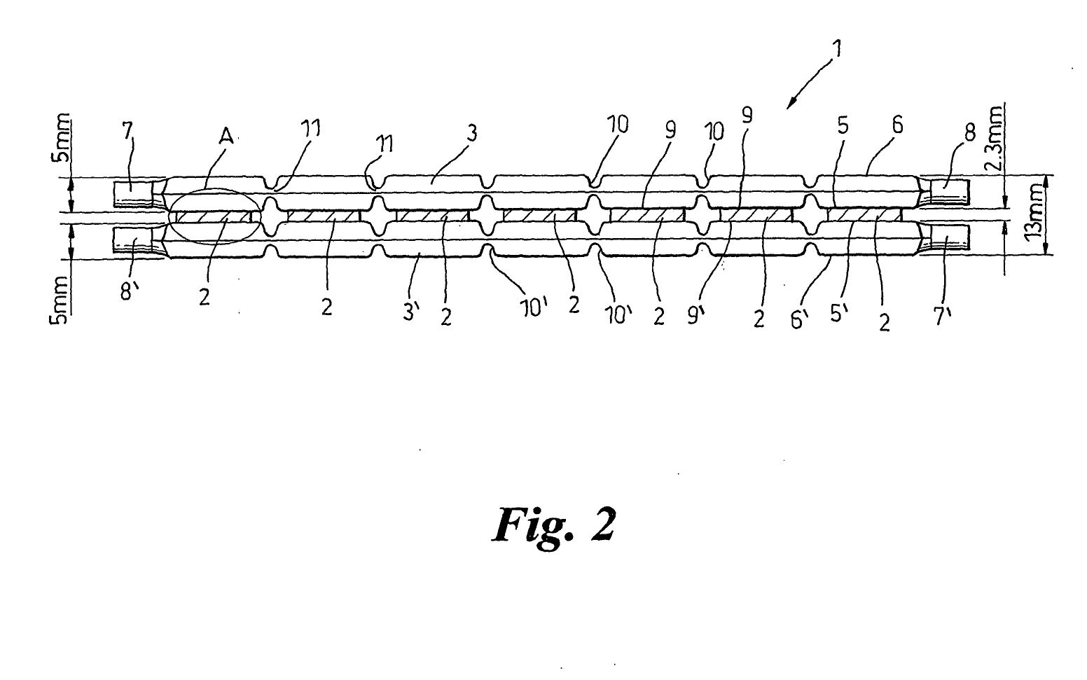

FIG. 2 is a side view of the thermoelectric module shown in FIG. 1;

FIG. 3 is a view, to an enlarged scale, of area A of FIG. 2 depicting one form of thermoelectric element;

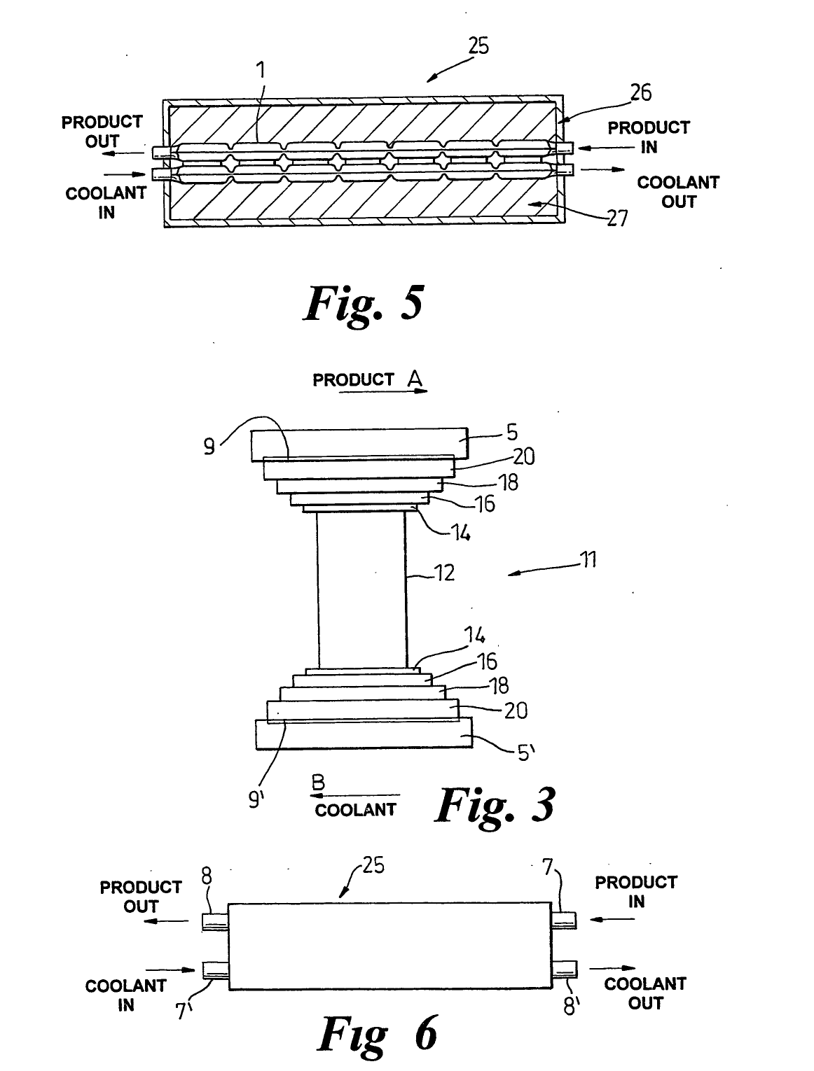

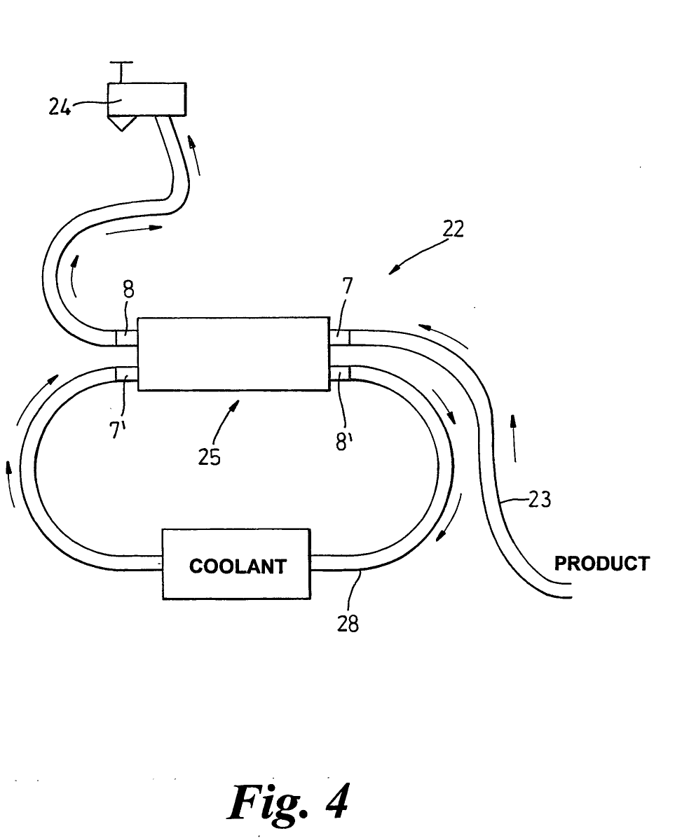

FIG. 4 is a diagrammatic illustration of a beverage dispense system having a cooler employing the thermoelectric module of FIGS. 1 and 2 for cooling the beverage;

FIG. 5 is a diagrammatic side view, partly in section, of the cooler of FIG. 4;

FIG. 6 is a side view of the cooler shown in FIG. 5 illustrating the direction of flow of fluids through the cooler;

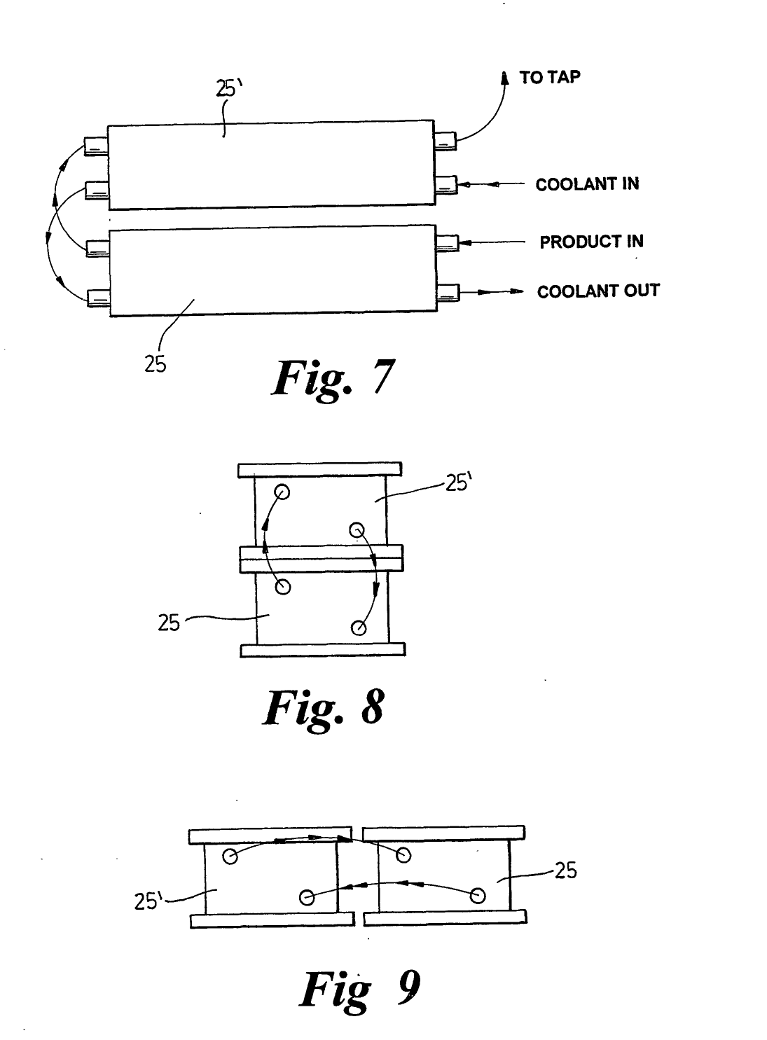

FIG. 7 shows two coolers connected in series;

FIG. 8 is an end view showing the two coolers of FIG. 7 stacked one on top of the other;

FIG. 9 is an end view showing the two coolers of FIG. 7 arranged side by side;

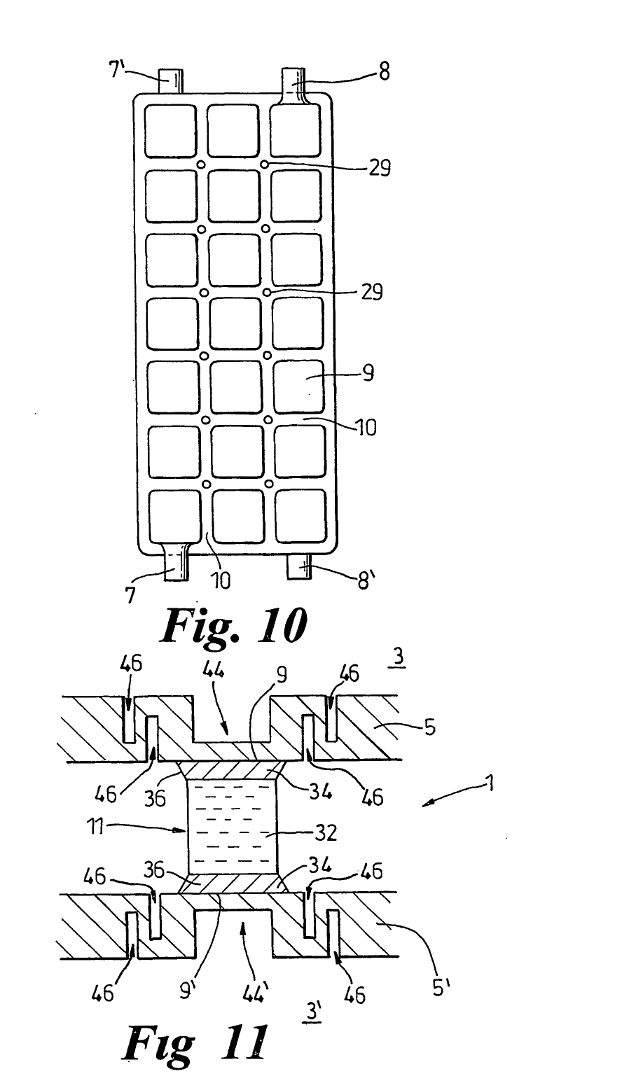

FIG. 10 is a plan view showing a modification to the thermoelectric module of FIG. 1; and

FIG. 11 is a view, to an enlarged scale, showing a further modification to the thermoelectric module of FIG. 1.

Referring first to FIGS. 1 and 2 of the drawings, a thermoelectric module 1 is shown comprising a plurality of thermoelectric devices 2 located between a pair of fluid chambers 3,3′.

Each chamber 3,3′ forms a flow line for passage of a fluid and the thermoelectric devices 2 are arranged so that fluid flowing through chamber 3 is cooled by thermal contact with a cold side of the thermoelectric devices 2 and fluid flowing through chamber 3′ is heated by thermal contact with a hot side of the thermoelectric devices 2.

The fluid flowing through chamber 3 may be a product such as a beverage that is to be cooled prior to dispense with the fluid flowing through chamber 3′ being a coolant such as water to remove heat.

Chamber 3 is formed by two rectangular metal plates 5,6 welded together around the peripheral edges of the plates 5,6. In this embodiment, the chamber 3 has a length of approximately 215 mm, a width of about 95 mm and a depth of about 5 mm.

An inlet 7 is provided in a corner at one end of the chamber 3 and an outlet 8 is provided in the diagonally opposite corner at the other end for connecting the chamber 3 to a fluid line. In this embodiment, the plates 5,6 are made of stainless steel compatible with the fluid flowing through the chamber 3.

Each plate 5,6 has a plurality of lands 9 separated from one another by grooves 10 extending longitudinally and transversely. The grooves 10 are formed in the surface of the plates 5,6 by pressing or other suitable means. In this embodiment, each land 9 is approximately 25 mm×25 mm square and the grooves 10 are about 5 mm wide.

As shown, the lands 9 and grooves 10 divide the surface area of the plates 5,6 to form a regular pattern in which there are seven rows of lands 9 with three lands 9 in each row, i.e. a total of twenty one lands 9. The lands 9 are of the same square shape and size and form separate, co-planar flat areas or regions in the surface of the plates 5,6.

The plates 5,6 are joined together to align the lands 9 and grooves 10 of one plate with those of the other plate. As best shown in FIG. 2, the depth of the grooves 10 is slightly less than the depth of the plates 5,6. In this way, the grooves 10 of one plate form a series of narrow gaps 11 with the opposed grooves 10 of the other plate that restrict flow of fluid through the chamber 3 and promote turbulence that assists heat transfer as described later herein.

Chamber 3′ is similar to chamber 3 and the construction thereof will be understood from the description of chamber 3. For convenience, like reference numerals with a single prime are used to indicate parts of the chamber 3′ corresponding to chamber 3.

In the assembled module 1, the chambers 3,3′ are arranged with the lands 9,9′ and grooves 10,10′ of the facing plates 5,5′ aligned with each other and the thermoelectric devices 2 arranged between each pair of opposed lands 9,9′ as shown in FIG. 2. The inlet 7′ and outlet 8′ of chamber 3′ are reversed and arranged at the opposite corners of the module with respect to the inlet 7 and outlet 8 of chamber 3 so that fluid flows through the chambers 3,3′ in opposite directions as shown by the arrows in FIG. 1.

Each of the thermoelectric devices 2 comprises a plurality of thermoelectric elements 11 arranged in side by side relation between the lands 9,9′. One of the thermoelectric elements 11 will now be described in more detail with reference to FIG. 3, it being understood that the other thermoelectric elements 11 are similar.

As shown, thermoelectric element 11 has a central semi-conductor layer 12 sandwiched on each side by a solder layer 14, a barrier layer 16 of gold, an electrically conducting circuit layer 18 of silver, and an electrically insulating glaze layer 20. The layer 18 is formed by silk screen printing a silver emulsion. The barrier layer 16 prevents poisoning of the semi-conductor layer 12 by migration of silver from layer 18. In a modification (not shown), the semi-conductor layer 12 is provided on each side with a nickel barrier layer and the barrier layer 16 may be omitted.

As will now be appreciated, the layers 12,14,16,18,20 are bonded to each other and the glaze layers 20 are bonded to the lands 9,9′. In this way, the assembly of the chambers 3,3′ with the thermoelectric elements 11 making up the thermoelectric devices 2 forms an integrated unit in which each thermoelectric device 2 is integral with the plates 5,5′ of both fluid chambers 3,3′. As a result, when the thermoelectric devices 2 are connected to an electrical supply, a current can be passed in direction to generate a cold side that cools plate 5 of chamber 3 and a hot side that heats plate 5′ of chamber 3′.

This can then be used to cool a product, e.g. a beverage, by passing the product through the chamber 3 as indicated by arrow A in FIG. 3. At the same time, the generated heat is removed by passing a coolant, e.g. water, through the chamber 3′ as indicated by arrow B in FIG. 3.

The number of thermoelectric devices 2 may be chosen to provide any desired cooling load. In this embodiment, one thermoelectric device 2 is provided between each pair of lands 9,9′, ie a total of twenty one thermoelectric devices 2, with each thermoelectric device 2 producing a product cooling load of around 10-15 watts giving a total product cooling load for the module 1 in the range of approximately 200-300 watts. It will be understood however that more than one thermoelectric device 2 may be provided between each pair of lands 9,9′.

A control system (not shown) is provided for controlling the power supply to the thermoelectric devices 2. The thermoelectric devices 2 may be arranged to form a single group in which all the thermoelectric devices 2 are either on or off. More preferably, however, the thermoelectric devices 2 are arranged separately or in sub-groups so that individual thermoelectric devices 2 or sub-groups of thermoelectric devices 2 may be either on or off. For example, in this embodiment, there are seven rows of thermoelectric devices 2 with three thermoelectric devices 2 in each row and the thermoelectric devices 2 in each row may form a sub-group operable independently of the thermoelectric devices 2 in the other rows.

In this way, the operation of the thermoelectric devices 2 may be adjustable to vary the cooling load of the module 1 according to the cooling requirement. The cooling load may be set manually or automatically in response to requirements, for example a higher cooling load may be required in summer than in winter.

Sensors (not shown) may be provided to monitor fluid temperature and provide a signal to the control system for adjusting the cooling load to achieve a desired cooling effect. For example, where the required product temperature can be obtained with a lower cooling load, individual thermoelectric devices 2 or sub-groups of thermoelectric devices 2 may be switched off to reduce the total product cooling load of the module 1.

Sensors (not shown) may also be provided to monitor fluid pressure and provide a signal to the control system to indicate the presence or absence of coolant or product and of flow/no flow conditions.

The heating and cooling of the plates 5,5′ gives rise to a significant temperature differential between the hot and cold sides which may be as high as 40° C. The thermoelectric devices 2 are integral with the plates 5,5′ and the thermal expansion and contraction generated by the temperature differential can lead to stress forces between the layers of the thermoelectric devices 2 which, if uncontrolled, could cause separation of the layers leading to failure of one or more of the thermoelectric devices 2.

The formation of the heat conducting surfaces 5,5′ with lands 9,9′ separated by grooves 10,10′ provides a degree of flexibility that acts to relieve the stress caused by the thermal expansion and contraction created during operation of the module 1 and prevent stress loads sufficient to cause separation of the layers of the thermoelectric devices 2 from each other an/or from the heat conducting surfaces 5,5′. In this way, the integrity of the module 1 is maintained.

Referring now to FIGS. 4 to 6, there is shown a beverage dispense system 22 having a beverage supply line 23 connected to a source of beverage (not shown). The beverage may be alcoholic, eg beer or lager, or non-alcoholic (carbonated or uncarbonated), eg cola, fruit juice, water. The supply line 23 delivers the beverage to a dispense point 24 where it is dispensed on demand into a glass or the like by opening an outlet such as a tap. Many beverages, especially beers and lagers, are required to be dispensed at temperatures lower than the beverage can be efficiently stored.

In order to cool the beverage to the required dispense temperature, a cooler 25 is provided in the supply line 23 between the source and the dispense point 24, usually close to the dispense point 24 so as to cool the beverage immediately prior to dispense.

The cooler 25 comprises the thermoelectric module 1 of FIGS. 1 and 2 housed in a casing 26 and surrounded by thermal insulation 27 to reduce the effect of ambient temperature changes on the operation of the cooler.

The inlet 7 and outlet 8 of the chamber 3 are connected to the supply line 23 for passing the beverage through the chamber 5 and the inlet 7′ and 8′ of the chamber 5′ are connected to a recirculation loop 28 for a coolant such as cold water.

The cooler 25 is operable in response to activation of a dispense to cool the beverage passing through the chamber 5 to the required dispense temperature. The volume of beverage between the cooler 25 and the dispense point is small so that any increase in temperature of the beverage in this region between dispenses has a negligible effect on the temperature of the dispensed beverage. In a modification (not shown) a beverage recirculation loop may be provided for the beverage between the cooler 25 and dispense point to maintain the beverage at the required dispense temperature.

For some applications, especially where the same supply line serves several dispense points, one cooler may not provide sufficient cooling to provide an acceptable flow rate of beverage cooled to the required temperature to meet demand. In this case, two or more coolers 25 may be arranged in series with an appropriate control system to operate the coolers 25 to provide a supply of beverage cooled to the required temperature according to the demand. The coolers 25 may have the same or different cooling powers and the control system may operate the coolers separately or in combination to meet the cooling requirement.

FIG. 7 shows an arrangement of two coolers 25,25′ connected in series with the flow of beverage indicated by single headed arrows and the flow of coolant indicated by double headed arrows. The coolers 25,25′ may be stacked on top of each other as shown in FIG. 8 or arranged side by side as shown in FIG. 9. It will be understood that units consisting of one, two or more coolers 25 may be employed to provide any desired cooling power.

Referring now to FIG. 10, there is shown a modification to the module of FIGS. 1 to 3 in which like reference numerals are used to indicate corresponding parts. The plates 5,6 of chamber 3 are provided with internal bosses 29 that further control flow of beverage through the chamber 3 and help to generate turbulence that enhances heat transfer between the beverage and the thermoelectric devices 2. In this way, efficiency of the module 1 is improved. Similar bosses may be provided in chamber 3′ to enhance heat transfer between the thermoelectric devices 2 and the coolant.

With reference now to FIG. 11, there is shown another modification to the module of FIGS. 1 to 3 in which like reference numerals are used to indicate corresponding parts. The module 1 has the heat conducting plates 5,5′ of chambers 3,3′ connected by thermoelectric elements 11 (one only shown) extending between and integral with flat land regions 9,9′ of the plates. The thermoelectric element 11 has a semi-conductor layer 32 having the glaze/electrical circuit, protective and solder layers similar to those of FIG. 1 on each side but shown here for convenience as a single composite layer 34.

The composite layer 34 has been dimensioned and shaped as indicated at its edges 36 to have some “give” during any thermal movement. This provides a degree of flexibility that helps to relieve stress caused by thermal expansion and contraction of the module 1 thereby reducing stress and assisting in maintaining integrity of the module 1.

In addition, the heat conducting surfaces 5,5′ are modified to relieve stress on the thermoelectric devices 2 and assists in maintaining the integrity of the module 1. In particular, recesses 44 are provided on the underside of the lands 9,9′ remote from the thermoelectric devices 2, eg by chemical etching where the plates 5,5′ are made of metal. The recesses 44 contribute to a reduction in the thermal gradient in the region of the thermoelectric devices 2 that helps to counter the effects of thermal expansion and contraction of the module. In addition, the plates 5,5′ are provided with slots 46,46′ in their opposite faces. The slots 46,46′ overlap in the centre region of the plates 5,5′ and provide a “spring” effect adjacent to the lands 9,9′ giving a degree of flexibility that helps to counter the effects of thermal expansion and contraction of the module 1.

As will be appreciated, the present invention provides a thermoelectric module having one or more thermoelectric devices integral with heat conducting surfaces on the hot and cold sides of the devices for transferring heat to and from fluids directly contacting the surfaces. In this way, the invented module forms an integrated unit which eliminates the inefficient boundaries for heat transfer found in existing thermoelectric modules and avoids the assembly problems of existing thermoelectric modules. For example, the use of thermal grease to improve heat transfer is avoided.

Furthermore, by forming the thermoelectric devices integrally with the heat conducting surfaces of the module, facilitates manufacture by allowing the use of the fabrication techniques such as silk screen printing to form one or more layers of the thermoelectric devices. This enables the thermoelectric devices to be produced with a high degree of accuracy and may allow closer packing of the thermoelectric devices leading to an increase in cooling power without significantly increasing the overall size of the module. Alternatively, the size of the module may be reduced without sacrificing cooling power.

Although the invention has been described with particular reference to application of the thermoelectric module for cooling a product, eg a beverage, to a desired temperature, it will be apparent the thermoelectric module could equally be used for heating a product to a desired temperature by reversing the operation of the thermoelectric devices so that the product contacts the heat conducting surface associated with the hot side of the thermoelectric device(s).

In this way, it may be possible to control the temperature of a fluid with a high degree of accuracy by controlling individual thermoelectric devices or sub-groups of thermoelectric devices within the module to heat or cool the product. For example, the control system may switch individual thermoelectric devices or sub-groups of thermoelectric devices within the module to transfer heat to or from a fluid to heat or cool the fluid in response to a detected difference between the required temperature and the actual temperature of the fluid.

Thus, individual thermoelectric devices or sub-groups of thermoelectric devices can be selectively controlled to provide achieve a required product temperature by cooling the product or heating the product or by a combination of cooling and heating the product. For example, any of the thermoelectric devices may be switched on individually or in sub-groups to control the direction of heat transfer to obtain and maintain a required product temperature. In this way, the product may be cooled by the thermoelectric device(s) in one zone or section of the module and heated by the thermoelectric device(s) in another zone or section. Additionally, if heat transfer to or from the product is not required in any zone or section of the module, the thermoelectric device(s) may be switched off.

Moreover, it will be recognised that the invention is not limited to controlling the temperature of a beverage and that the thermoelectric module may be employed more widely. For example, the thermoelectric module may have application in the medical field for controlling temperature of a fluid where accurate control of temperature is important. The thermoelectric module may also have application as a heat pump for heat recovery from waste fluids such as domestic or industrial waste water.

It will be understood that the above-described examples are intended to illustrate the diverse range and application of the invented thermoelectric modules and that features of the embodiments may be used separately or in combination with any other feature of the same or different embodiments to produce a thermoelectric module that can be used for heating or cooling a fluid product as desired.

Moreover, while the specific materials and/or configuration of the modules described and illustrated are believed to represent the best means currently known to the applicant for producing modules having application for heating or cooling a product, it will be appreciated that the invention is not limited thereto and that various modifications and improvements can be made within the spirit and scope of the claims.

1. A thermoelectric module comprising a first flow line for a first fluid, a second flow line for a second fluid, and at least one thermoelectric device between a heat conducting surface of the first flow line and a heat conducting surface of the second flow line characterised in that the thermoelectric device is integral with the heat conducting surfaces of the first and second flow lines.

2. A thermoelectric module according to claim 1 wherein the heat conducting surfaces of the first and second flow lines are of metal or ceramic.

3. A thermoelectric module according to claim 1 or claim 2 wherein, the thermoelectric device comprises a plurality of thermoelectric elements having a printed electrically conducting circuit layer on each side of a central semi-conductor layer.

4. A thermoelectric module according to claim 3 wherein the heat conducting surface of either flow line is of an electrically conducting material and a layer of electrically insulating material is applied between the heat conducting surface and the adjacent electrically conducting circuit layer.

5. A thermoelectric module according to claim 4 wherein, the glaze contains thermally conductive material

6. A thermoelectric module according to any one of claims 3 to 5 wherein the printed electrically conducting circuit layer is of silver and a protective barrier layer is provided to prevent poisoning of the semiconductor layer by the silver.

7. A thermoelectric module according to any one of claims 3 to 6 wherein the printed electrically conducting circuit layer is soldered to the semi-conductor layer.

8. A thermoelectric module according to any one of the preceding claims wherein the heat conducting surface of each flow line is provided by a plate of rectangular shape for securing to a matching plate to form a fluid chamber of rectangular section having an inlet at one end and an outlet at the other end for connection of the flow line to a fluid line.

9. A thermoelectric module according to claim 8 wherein each chamber is adapted to direct the flow or to provide turbulence to the flow between the inlet and outlet.

10. A thermoelectric module according to claim 8 or claim 9 wherein the plates are hardened to increase stiffness and thereby provide increased support for the module.

11. A thermoelectric module according to any one of claims 8 to 10 wherein a bursting disc to relieve excess pressure is provided in the plates.

12. A thermoelectric module according to any one of the preceding claims wherein the thermoelectric device is applied to a flat area or region of each heat conducting surface.

13. A thermoelectric module according to any one of the preceding claims wherein the module comprises a plurality of thermoelectric devices between and integral with the heat conducting surfaces of the first and second flow lines.

14. A thermoelectric module according to any one of the preceding claims wherein stress relief means is provided to counter the effect of thermal expansion and contraction of the module.

15. A thermoelectric module according to claim 14 wherein the stress relief means provides flexing in selected areas or regions to reduce stresses within the module and assist in maintaining integrity of the module.

16. A thermoelectric module according to claim 15 wherein, the heat conducting surfaces of each flow line are formed with lands separated by channels, the lands providing flat areas or regions for applying one or more thermoelectric devices and the channels helping to relieve stress during thermal expansion and contraction of the module and countering stresses to assist in maintaining the integrity of the module.

17. A thermoelectric module according to claim 16 wherein the heat conducting surfaces are pre-formed with the stress relief means prior to formation of the thermoelectric device(s) and assembly of the module.

18. A thermoelectric module according to any one of claims 14 to 18 wherein stress relief is provided by locally reducing the thickness of the heat conducting surfaces in the region of the thermoelectric device(s) to reduce thermal gradients and/or by providing the heat conducting surfaces with slots or similar formations adjacent to the thermoelectric device(s) to act like springs.

19. A thermoelectric module according to any one of the preceding claims wherein thermistors are printed onto the electrically conducting circuit layer to assist with temperature control of the module.

20. A thermoelectric module according to any one of the preceding claims wherein a control circuit is mounted on the same substrate as the semi-conductor thermoelectric elements.

21. A thermoelectric module according to any one of the preceding claims wherein pressure sensors are printed onto the module.

22. A thermoelectric module according to any one of the preceding claims wherein the number and arrangement of the thermoelectric devices is chosen to provide the module with any desired power for cooling/heating a fluid.

23. A thermoelectric module according to claim 22 wherein the power is adjustable by controlling the power supply to the thermoelectric devices according to the cooling/heating requirement.

24. A thermoelectric module according to any one of the preceding claims wherein the thermoelectric device can be switched to reverse the direction of heat transfer.

25. A thermoelectric module according to claim 24 wherein a plurality of thermoelectric devices are provided and the direction of heat transfer can be selectively controlled to provide cooling or heating or a combination of cooling and heating of a fluid flowing through the module.

26. A method of manufacturing a thermoelectric module comprising providing first and second spaced heat conducting surfaces and forming a thermoelectric device between the first and second heat conducting surfaces with an outer layer on each side of a semi-conductor layer integral with the first and second heat conducting surfaces whereby the first and second heat conducting surfaces form an integrated unit with the thermoelectric device.

27. A method according to claim 26 wherein a plurality of thermoelectric devices are formed between the first and second heat conducting surfaces.

28. A method according to claim 27 wherein the heat conducting surfaces are arranged to form part of fluid chambers for passage of fluids to be heated or cooled by direct contact with the heat conducting surfaces.

29. A thermoelectric module for heating a first fluid and cooling a second fluid comprising at least one thermoelectric device integral with a pair of spaced heat conducting surfaces for contact with the first and second fluids respectively, and means for relieving stress caused by thermal expansion and contraction of the module.

30. A thermoelectric cooler for a beverage, the cooler comprising a heat conducting surface for a beverage to be cooled, a heat conducting surface for a coolant, the heat conducting surfaces being connected by at least one thermoelectric device integral with the heat conducting surfaces such that, in use, a cold side of the or each thermoelectric device is arranged to remove heat from a beverage, and a hot side of the or each thermoelectric device is arranged to transfer heat to a coolant.

31. A thermoelectric cooler according to claim 30 wherein the cooler is provided in a beverage supply line for controlling the dispense temperature of a beverage delivered to a dispense point.

32. A thermoelectric cooler according to claim 30 wherein a plurality of coolers are provided to achieve the required cooling.

33. A thermoelectric cooler according to claim 32 wherein the coolers are connected in series with suitable control means for controlling operation in response to a particular cooling requirement.

34. A beverage dispense system comprising a source of a beverage to be dispensed, a supply line for delivering the beverage from the source to a dispense point, and at least one thermoelectric cooler according to the fourth aspect of the invention positioned between the source and the dispense point for lowering the temperature of the beverage to a required temperature for dispense.

35. A method of controlling a dispense temperature of a beverage comprising providing a supply of a beverage at a first temperature and cooling the beverage to a second temperature corresponding substantially to a desired dispense temperature by passage through a thermoelectric module having a cold surface for contact with the beverage and a hot surface for contact with a coolant, and at least one thermoelectric device integral with the hot and cold surfaces.

36. A method of controlling the temperature of a fluid comprising providing a supply of a fluid and transferring heat to or from the fluid to a obtain desired fluid temperature by passage through a thermoelectric module having a first surface for contact with the fluid and a second surface for contact with a further fluid, and at least one thermoelectric device integral with the first and second surfaces.

37. A method according to claim 36 wherein heat is transferred from the fluid to cool the fluid.

38. A method according to claim 36 wherein heat is transferred to the fluid to heat the fluid.

39. A method according to claim 36 wherein a plurality of thermoelectric devices are provided and the method includes the step of selectively controlling heat transfer to heat or cool the fluid in response to the fluid temperature.

40. A thermoelectric module substantially as hereinbefore described with reference to FIGS. 1 to 3 of the accompanying drawings.

41. A thermoelectric module substantially as hereinbefore described with reference to FIGS. 1 to 3 of the accompanying drawings as modified by FIG. 10 or FIG. 11 of the accompanying drawings.

42. A beverage dispense system employing a thermoelectric module substantially as hereinbefore described with reference to FIGS. 4 to 9 of the accompanying drawings.

43. A method of manufacturing a thermoelectric module substantially as hereinbefore described with reference to FIGS. 1 to 3 of the accompanying drawings.

44. A method of manufacturing a thermoelectric module substantially as hereinbefore described with reference to FIGS. 1 to 3 of the accompanying drawings as modified by FIG. 10 or FIG. 11 of the accompanying drawings.
